(19) United States
(12) Patent Application Publication
(10) Pub. No.: US 2011/0116267 A1
(43) Pub. Date: May 19, 2011

(54) HEAT DISSIPATION STRUCTURE OF AN ELECTRONIC ELEMENT

(76) Inventor: Tsung-Hsien HUANG, Yonghe City (TW)

(21) Appl. No.: 12/619,244

(22) Filed: Nov. 16, 2009

(51) Int. Cl. F21S 4/00; H05K 7/20

(52) U.S. Cl. 362/249.02; 361/709

(57) ABSTRACT

A heat dissipation structure of an electronic element includes a cooling fin, an aluminum heat dissipation seat which is provided on the cooling fin and at least one electronic element which is provided on the aluminum heat dissipation seat. At least one heat conducting copper column is provided on the aluminum heat dissipation seat by being tightly forced in or by a stamping method with a mold, and is located corresponding to the electronic element. Therefore, the present invention can conduct heat from the electronic elements, can reduce a manufacturing cost, can accelerate production, can decrease a manufacturing process, is environment friendly and is provided with a high heat dissipation efficiency.

### BACKGROUND OF THE INVENTION

a) Field of the Invention

The present invention relates to a heat dissipation structure and more particularly to a heat dissipation structure of an electronic element, which is provided with a low production cost, can be quickly manufactured, is provided with fewer manufacturing process, is environmental friendly and is provided with a high heat dissipation efficiency.

b) Description of the Prior Art

An LED (Light Emitting Diode) utilizes a principle that electric energy is directly converted into light energy, wherein a voltage is applied between a positive pole and a negative pole in a semiconductor and when an electric current passes through such that electrons are combined with holes, rest of energy will be released in a form of light. According to a material used, light of a different wavelength will be produced depending upon an energy level of photons. Therefore, the LED is provided with advantages of high brightness, energy saving and long lifetime of usage and is thus broadly applied in all kinds of technologies and daily lives, thereby becoming an indispensable lighting tool in the world.

Only 15˜20% of power inputted to the LED is converted into light, and the rest 80˜85% of power will be converted into heat. If the heat is not expelled out timely, then an interface temperature of an LED chip will be too high that a lighting efficiency and a lifetime of usage can be affected. In a practical application, a space and location where the high power and high brightness LED is used for illuminating will play a major role in the effect of heat dissipation.

A conventional LED lamp heat dissipation module includes basically an LED lamp, a circuit board, a cooling fin and a heat conducting copper column, wherein the heat conducting copper column is in a T shape, a hole is provided on the circuit board at the location of the LED lamp and the cooling fin is provided with a dent hole at the hole of the circuit board. The heat conducting copper column is put into the dent hole, a T-shaped end is located in the hole of the circuit board and is attached beside the dent hole of the cooling fin. As a result, the LED lamp is directly in contact with the T-shaped end of the copper column such that heat can be directly transmitted to the cooling fin, thereby achieving an object of quickly dissipating the heat.

However, when the aforementioned LED lamp heat dissipation module is used, following issues and shortcomings actually exist to be improved.

For the heat dissipation method, a hole punching operation has to be carried out on an aluminum heat dissipation seat to form the dent hole, and then the heat conducting copper column is put into the dent hole. This method not only wastes time and labor works, but also is not cost-benefited. In addition, a dent hole manufacturing step is added to the process, which will increase the cost and delay the production time. Therefore, industrial competitiveness is imperfect. Besides, as the holes need to be drilled in advance for this prior art, the dent hole can be easily made too big or too small, resulting in imperfect adaptation as tightness is not good when the heat conducting copper column is put into the dent hole (a gap is generated at peripheries of the copper column), thereby decreasing the heat dissipation effect. Moreover, as the gap is generated, impurities can be easily formed in the gap to affect the heat dissipation effect. On the other hand, as the heat dissipation module is manufactured using a thermal expansion principle, the manufacturing process will waste time and materials.

### SUMMARY OF THE INVENTION

The primary object of the present invention is to provide a heat dissipation structure of an electronic element, wherein an aluminum heat dissipation seat of the heat dissipation structure is connected with a cooling fin and is provided with at least one heat conducting copper column which is fixed on the aluminum heat dissipation seat by being tightly forced in or by a stamping method, with a mold. Plural electronic elements are provided respectively on the aluminum heat dissipation seat at locations corresponding to the heat conducting copper columns. When the electronic elements start to operate to generate heat energy, by the corresponding provision of the heat conducting copper columns, the heat energy can be effectively and quickly transmitted out. Therefore, by the aforementioned technologies, the issues existing the conventional LED lamp heat dissipation module that for the heat dissipation method, the hole punching operation has to be carried out on the aluminum heat dissipation seat to form the dent hole, and then the heat conducting copper column is put into the dent hole, thus this method not only wastes time and labor works, but also is not cost-benefited; in addition, the dent hole manufacturing step is added to the process, which will increase the cost and delay the production time, therefore, the industrial competitiveness is imperfect; besides, as the holes need to be drilled in advance, the dent hole can easily made too big or too small, resulting in the imperfect adaptation as the tightness is not good when the heat conducting copper column is put into the dent hole (the gap is generated at peripheries of the copper column), such that the heat dissipation effect is reduced; moreover, as the gap is generated, the impurities can be easily formed in the gap to affect the heat dissipation effect; and on the other hand, as the heat dissipation module is manufactured using the thermal expansion principle, the manufacturing process will waste the time and materials, can be solved, thereby improving the heat conduction effect by putting the heat conducting copper columns on the aluminum heat dissipation seat by the stamping method or by being tightly forced in, and by allowing the heat conducting copper columns to correspond to the electronic elements which generate the heat energy. In addition, the present invention can reduce the manufacturing cost, accelerate the production, decrease the manufacturing process and is environmental friendly.

To enable a further understanding of the said objectives and the technological methods of the invention herein, the brief description of the drawings below is followed by the detailed description of the preferred embodiments.

### BRIEF DESCRIPTION OF THE DRAWINGS

FIG. 1 shows a three-dimensional schematic view of a preferred embodiment of the present invention.

FIG. 2 shows a three-dimensional exploded view of the preferred embodiment of the present invention.

FIG. 3 shows a schematic view of heat dissipation of the preferred embodiment of the present invention.

FIG. 4 shows a three-dimensional schematic view of an implementation of another preferred embodiment of the present invention.

FIG. 5 shows an exploded view of the implementation of another preferred embodiment of the present invention.

### DETAILED DESCRIPTION OF THE PREFERRED EMBODIMENTS

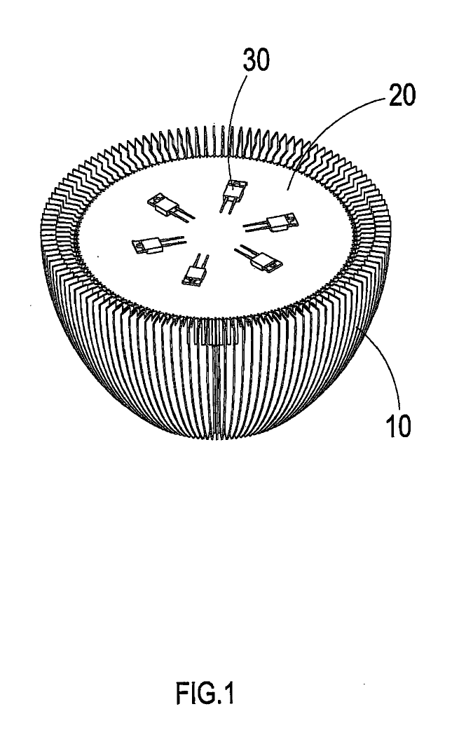

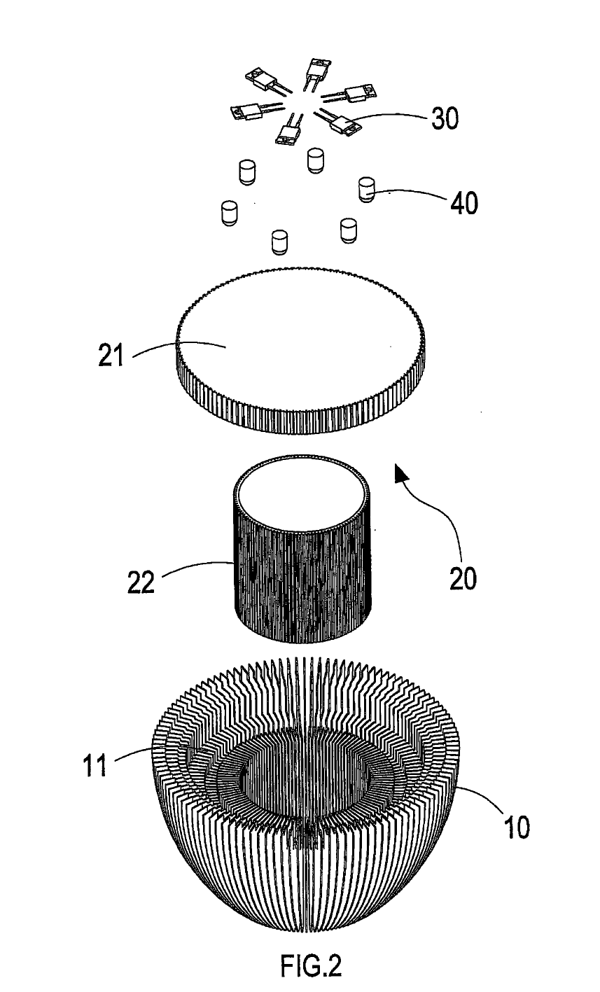

Referring to FIG. 1 and FIG. 2, it shows a three-dimensional schematic view and a three-dimensional exploded view, of a preferred embodiment of the present invention. As shown in the drawings, the present invention comprises a cooling fin 10, an aluminum heat dissipation seat 20 which is provided on the cooling fin 10 and at least one electronic element 30 which is provided on the aluminum heat dissipation seat 20 and can be an LED lamp or any element that generates heat energy. The aluminum heat dissipation seat 20 is defined with at least one heat conducting copper column 40 at a location corresponding to the electronic element 30. The aforementioned heat conducting copper columns 40 are provided on the aluminum heat dissipation seat 20 by being tightly forced in with a mold or can be further provided on the aluminum heat dissipation seat 20 by a forced stamping method. In the present embodiment, the aluminum heat dissipation seat 20 is formed by a main unit 21 and a barrel 22 which is abutted below the main unit 21; whereas, the main unit 21 is provided on a platform 11 which is formed at an inner side of the cooling fin 10.

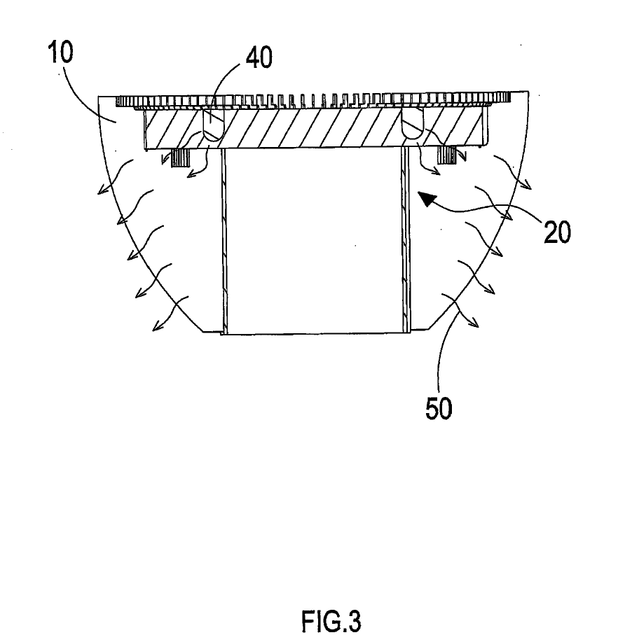

Referring to FIG. 2 and FIG. 3, it shows the three-dimensional exploded view and a schematic view of heat dissipation of the preferred embodiment of the present invention. As shown in the drawings, the aluminum heat dissipation seat 20 of the heat dissipation structure is connected with the cooling fin 10 and is provided with at least one heat conducting copper column 40 which is tightly forced in (such as by a stamping method) with a mold, and the corresponding locations of the heat conducting copper columns 40 are provided respectively with the electronic element 30. When the electronic elements 30 start to operate to generate heat energy 50, by the corresponding provision of the heat conducting copper columns 40, the heat energy 50 of the electronic elements 30 can be transmitted out quickly and then be expelled out through the heat conducting copper columns 40 from the cooling fin 10.

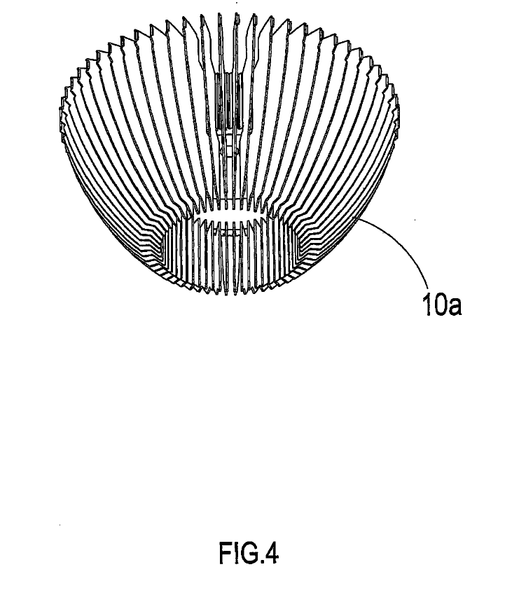

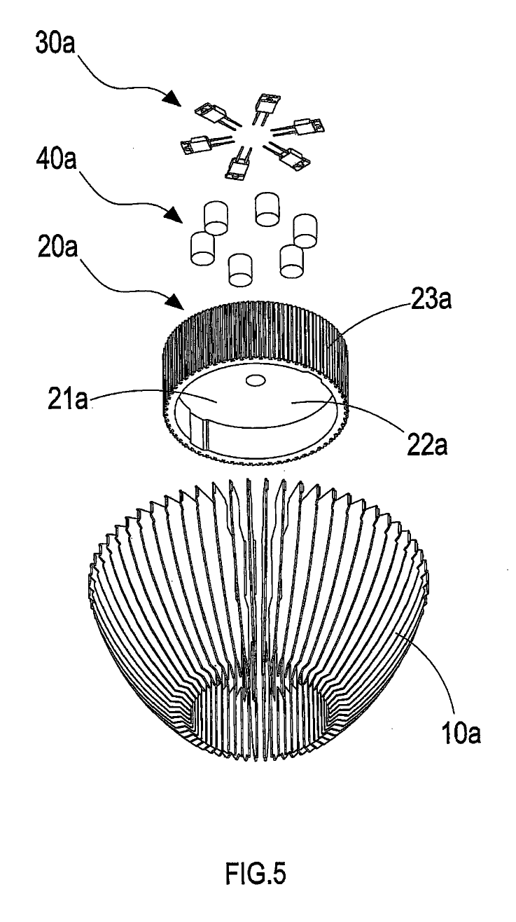

Referring to FIG. 4 and FIG. 5, it shows a three-dimensional schematic view and an exploded view of an implementation of another preferred embodiment of the present invention. As shown in the drawings, the heat dissipation structure includes a cooling fin 10a, an aluminum heat dissipation seat 20a, at least one heat conducting copper column 40a and at least one electronic element 30a. The cooling fin 10a is provided with the aluminum heat dissipation seat 20a which is defined with a groove 21a. The aluminum heat dissipation seat 20a is defined with the plural heat conducting copper columns 40a which are provided by being tightly forced in (e.g., by a stamping method) and corresponding locations of the heat conducting copper columns 40a are provide with the plural electronic elements 30a. In the present embodiment, the aluminum heat dissipation seat 20a is formed by a main unit 22a and a ring of wall 23a which is extended integrally from peripheries of the main unit 22a. The ring of wall 23a and the main unit 22a form the groove 21a and the ring of wall 23a is assembled at the inner side of the cooling fin 10a.

Accordingly, the keys of the heat dissipation structure of an electronic element, according to the present invention, to improve the prior art, include that:
1. The heat conducting copper columns 40 are provided on the aluminum heat dissipating seat 20 (as a density of the aluminum heat dissipation seat 20 is smaller than a density of the heat conducting copper columns 40) by being tightly forced in (e.g., by a stamping method) with a mold, which is provided with the advantages of quick production and fewer manufacturing process.
2. The heat conducting copper columns 40 are provided correspondingly with the electronic elements 30, respectively. Therefore, when the electronic elements 30 dissipate the heat energy 50, the heat energy 50 can be transmitted onto the cooling fin 10 by the heat conducting copper columns 40 and be expelled out, which is provided with the advantage of high heat dissipation efficiency.
3. As the heat conducting copper columns 40 can be put into the aluminum heat dissipation seat 20 without using the hole-drilling technology in advance, the materials will not be consumed to protect the environment.
4. As the heat conducting copper columns 40 are provided at the locations corresponding to the electronic elements 30 respectively, a quantity of the heat conducting copper columns 40 to be used can be selected, which is very well provided with the advantage of reducing the manufacturing cost in a present time where a cost of steel is extremely high.

It is of course to be understood that the embodiments described herein is merely illustrative of the principles of the invention and that a wide variety of modifications thereto may be effected by persons skilled in the art without departing from the spirit and scope of the invention as set forth in the following claims.

What is claimed is:

1. A heat dissipation structure of an electronic element comprising a cooling fin, an aluminum heat dissipation seat which is provided on the cooling fin and at least one electronic element which is provided on the aluminum heat dissipation seat, wherein the aluminum heat dissipation seat is defined with at least one heat conducting copper column which is at a location corresponding to the electronic element, and the heat conducting copper column is tightly forced onto the aluminum heat dissipation seat by a mold.

2. The heat dissipation structure of an electronic element according to claim 1, wherein the heat conducting copper column is further provided on the aluminum heat dissipation seat by a forced stamping method with a mold.

3. The heat dissipation structure of an electronic element according to claim 1, wherein the electronic element is an LED (Light Emitting Diode) lamp.

4. The heat dissipation structure of an electronic element according to claim 1, wherein the aluminum heat dissipation seat is formed by a main unit and a barrel which is abutted below the main unit, with the main unit being provided on a platform formed at an inner side of the cooling fin.

5. The heat dissipation structure of an electronic element according to claim 1, wherein the aluminum heat dissipation seat is formed by a main unit and a ring of wall which is extended integrally from peripheries of the main unit, with the ring of wall and the main unit forming a groove and the ring of wall being assembled at an inner side of the cooling fin.
